(19) United States
(12) Patent Application Publication
(10) Pub. No.: US 2016/0190181 A1
(43) Pub. Date: Jun. 30, 2016

(54) SEMICONDUCTOR DEVICE AND PRODUCTION METHOD THEREFOR

(71) Applicant: SHARP KABUSHIKI KAISHA, Osaka-shi, Osaka (JP)

(72) Inventors: Naoki UEDA, Osaka-shi (JP); Akihiro ODA, Osaka-shi (JP); Hirohiko NISHIKI, Osaka-shi (JP); Tohru OKABE, Osaka-shi (JP)

(21) Appl. No.: 14/650,681

(22) PCT Filed: Dec. 2, 2013
(86) PCT No.: PCT/JP2013/082341

§ 371 Date: Jun. 9, 2015

(30) Foreign Application Priority Data
Dec. 10, 2012 (JP) 2012-269789

(51) Int. Cl. H01L 27/12; H01L 29/786; G09G 3/36; H01L 29/45; H01L 29/417; H01L 29/24; H01L 29/66

(52) U.S. Cl. CPC H01L 27/1248; H01L 29/24; H01L 29/7869; H01L 27/1225; H01L 29/66969; H01L 27/1259; H01L 27/124; H01L 29/45; H01L 29/41733; G09G 3/3677; G09G 2310/0286; G09G 2300/0809

(57) ABSTRACT

A semiconductor device includes: a plurality of thin film transistors including a gate electrode, a gate dielectric layer, a semiconductor layer formed on the gate dielectric layer, and a source electrode and a drain electrode provided on the semiconductor layer; a source metal layer including a global line which supplies a common signal to the plurality of thin film transistors, the global line being made of the same electrically conductive film as the source electrode and drain electrode; and a dielectric protection layer covering the plurality of thin film transistors and the source metal layer. The source metal layer includes a lower layer and an upper layer stacked on a portion of the lower layer. The global line has a first layer structure including the lower layer and the upper layer, and at least a portion of each source electrode and of each drain electrode that is located on the semiconductor layer has a second layer structure including the lower layer but not including the upper layer.

### TECHNICAL FIELD

The present invention relates to a semiconductor device and a production method thereof.

### BACKGROUND ART

Active matrix substrates that are used for liquid crystal display devices, organic EL display devices or the like include a switching element for each pixel, e.g., a thin film transistor (hereinafter “TFT”). An active matrix substrate which includes TFTs as the switching elements is called a TFT substrate.

As such switching elements, TFTs whose active layers are an amorphous silicon film (hereinafter “amorphous silicon TFTs”) and TFTs whose active layers are a polycrystalline silicon film (hereinafter “polycrystalline silicon TFTs”) have been widely used. A TFT substrate has a display region that includes a plurality of pixels, such that a TFT is provided as a switching element for each pixel. The drain electrode of a TFT is connected to a pixel electrode. The source electrode is connected to a source bus line, or formed as an integral piece with the source bus line. In the region other than the display region of the TFT substrate (non-display region), some TFTs may also be used as circuit elements composing driving circuitry.

In the recent years, it has been proposed to use an oxide semiconductor as the material of the active layers of TFTs, instead of an amorphous silicon or a polycrystalline silicon. These TFTs are called “oxide semiconductor TFTs”. An oxide semiconductor provides a higher mobility than does an amorphous silicon. Therefore, oxide semiconductor TFTs can operate more rapidly than amorphous silicon TFTs. Moreover, an oxide semiconductor film is formed through a simple process as compared to a polycrystalline silicon film, and therefore is applicable to devices which require a large geometric area.

Patent Document 1 discloses an amorphous silicon TFT which is structured so that a gate electrode is disposed on the substrate side of the active layer (bottom gate structure). Patent Documents 2 to 4 disclose oxide semiconductor TFTs having a bottom gate structure. In these TFTs, the source and drain electrodes are partly provided on the active layer. A dielectric layer (passivation film) is provided above the source and drain electrodes, so as to cover the TFT. The passivation film restrains impurities and moisture from intruding into the active layer.

Generally speaking, the source and drain electrodes of a TFT are formed by patterning the same electrically conductive film. On a TFT substrate, lines such as source bus lines and terminals, etc., can be formed from the same electrically conductive film as the source and drain electrodes of the TFTs (see Patent Document 3). In the present specification, a layer including electrodes and lines that are formed from the same electrically conductive film as the source electrodes and source bus lines will be referred to as a “source metal layer”.

On the other hand, there may be cases where source bus lines are formed via an electrically insulative film over the source electrodes and drain electrodes of TFTs (see Patent Document 4). In such cases, a source bus line is to be connected to a source electrode within a contact hole which is created in the interlevel dielectric layer. Furthermore, Patent Document 5 discloses a circuit having transistors in which, above an interconnection layer (a local line layer) that includes the source and drain electrodes, another interconnection layer (a global line layer) is provided via an interlevel dielectric layer. The lines in the local line layer are connected to the lines in the global line layer via contact holes which are created in the interlevel dielectric layer. However, the constructions disclosed in Patent Documents 4 and 5 require more complicated production processes than does the construction of Patent Document 3 described above, because an interconnection layer needs to be further provided in addition to the interconnection layer that includes the source and drain electrodes.

### CITATION LIST

### Patent Literature

[Patent Document 1] Japanese Laid-Open Patent Publication No. 62-67872

[Patent Document 2] Japanese Laid-Open Patent Publication No. 2011-129926

[Patent Document 3] Japanese Laid-Open Patent Publication No. 2009-76894

[Patent Document 4] Japanese Laid-Open Patent Publication No. 2011-035387

[Patent Document 5] Japanese Laid-Open Patent Publication No. 2001-244267

### SUMMARY OF INVENTION

### Technical Problem

As described above, in terms of production processes, it is preferable in a TFT substrate that the source and drain electrodes of the TFTs and wiring lines such as the source bus lines and terminals, etc., are formed in the same layer (i.e., the source metal layer). In the case where the source and drain electrodes of the TFTs and wiring lines such as the source bus lines are formed in the same layer, a relatively thick film containing a low-resistance electrically conductive material is to be used as the electrically conductive film from which to form such electrodes and lines. This is in order to ensure a rapid circuit operation by keeping the line resistance low.

However, it was found through a study by the inventors that, when a thick electrically conductive film is used to form the source and drain electrodes, stepped portions emerging at the edges of these electrodes may reduce the covering ability of the passivation film that is formed thereupon. When the covering ability of the passivation film lowers so that voids (spaces and small pores) occur in the interior of the passivation film above the aforementioned stepped portions, impurities and moisture may intrude into the semiconductor layer through there. This may possibly deteriorate the TFT characteristics.

The above problem may also occur in conventional silicon semiconductor TFTs, but is particularly noted in oxide semiconductor TFTs. As compared to a silicon semiconductor layer, an oxide semiconductor layer is susceptible to fluctuations of its electrical characteristics due to moisture and impurities. For example, when moisture, hydrogen, or the like intrudes in an oxide semiconductor layer, a reduction reaction may occur in the oxide semiconductor, possibly causing oxygen deficiencies in the oxide semiconductor layer. If carrier electrons occur due to oxygen deficiencies, the oxide semiconductor layer will decrease in electrical resistance, so that desired TFT characteristics may not be obtained.

In view of the above circumstances, an objective of an embodiment of the present invention is, in a semiconductor device having thin film transistors, to restrain characteristics deteriorations in the thin film transistors that are caused by a decrease in the covering ability of a passivation film, while reducing an increase in the resistance of wiring lines within the source metal layer.

### Solution to Problem

A semiconductor device according to an embodiment of the present invention comprises: a substrate; a plurality of thin film transistors supported on the substrate, each of the plurality of thin film transistors including a gate electrode, a gate dielectric layer formed on the gate electrode, a semiconductor layer formed on the gate dielectric layer, and a source electrode and a drain electrode being provided on the semiconductor layer and electrically connected to the semiconductor layer; a source metal layer including the source electrodes and the drain electrodes and a global line which supplies a common signal to the plurality of thin film transistors, the global line being made of a same electrically conductive film as the source electrodes and the drain electrodes; and a dielectric protection layer covering the plurality of thin film transistors and the source metal layer, wherein, the metal layer includes a lower layer and an upper layer stacked on a portion of the lower layer; the global line has a first layer structure including the lower layer and the upper layer; and at least a portion of each source electrode and of each drain electrode that is located on the semiconductor layer has a second layer structure including the lower layer but not including the upper layer.

In one embodiment, the surface of the upper layer in the first layer structure is in contact with the dielectric protection layer; and the surface of the lower layer in the second layer structure is in contact with the dielectric protection layer.

In one embodiment, the lower layer includes a first layer, and the upper layer includes a second layer formed on the first layer by using a different material from that of the first layer.

In one embodiment, the source metal layer further includes global line-transistor connection lines which electrically connect the global line respectively to the plurality of thin film transistors, the global line-transistor connection lines having the second layer structure.

In one embodiment, the source metal layer further includes an inter-transistor connection line which electrically connects at least two of the plurality of thin film transistors, the inter-transistor connection line having the second layer structure.

In one embodiment, the lower layer is thinner than the upper layer.

In one embodiment, when viewed from a normal direction of the substrate, at least a portion of each source electrode and of each drain electrode that overlaps the gate electrode has the second layer structure.

In one embodiment, when viewed from a normal direction of the substrate, there is a distance of 10 μm or more between the global line and the semiconductor layer.

In one embodiment, the surface of channel regions of the plurality of thin film transistors is in contact with the dielectric protection layer.

In one embodiment, an etch stop layer is provided between the semiconductor layer and the source electrodes and drain electrodes of the plurality of thin film transistors.

In one embodiment, the semiconductor device comprises a shift register, wherein the shift register includes at least a part of the plurality of thin film transistors.

In one embodiment, the semiconductor device has a display region including a plurality of pixels, wherein each of the plurality of pixels includes at least one thin film transistor among the plurality of thin film transistors.

In one embodiment, the semiconductor layer is an oxide semiconductor layer.

In one embodiment, the oxide semiconductor layer comprises an In—Ga—Zn—O type oxide.

A production method for a semiconductor device according to an embodiment of the present invention is a production method for a semiconductor device including a plurality of thin film transistors and a global line which supplies a common signal to the plurality of thin film transistors, comprising: step (a) of forming a gate metal layer including a plurality of gate electrodes on a substrate; step (b) of forming a gate dielectric layer on the gate metal layer; step (c) of forming a semiconductor layer in plural parts on the gate dielectric layer to become active layers of the plurality of thin film transistors; step (d) of forming a first electrically conductive film on the semiconductor layer and the gate dielectric layer, and then forming a second electrically conductive film on the first electrically conductive film; step (e) of patterning the first electrically conductive film and the second electrically conductive film to form a source metal layer including source electrodes and drain electrodes of the plurality of thin film transistors and the global line, the source metal layer including a lower layer made of the first electrically conductive film and an upper layer made of the second electrically conductive film, the upper layer being stacked on a portion of the lower layer; and step (f) of forming a dielectric protection layer on the source metal layer, wherein, the global line has a first layer structure including the lower layer and the upper layer; and at least a portion of each source electrode and of each drain electrode that is located on the semiconductor layer has a second layer structure including the lower layer but not including the upper layer.

In one embodiment, step (e) comprises step (e1) of patterning the second electrically conductive film to form the upper layer, and step (e2), performed after step (e1), of patterning the first electrically conductive film to form the lower layer.

In one embodiment, the semiconductor device includes a global line region and a local line region; and step (e) comprises step (e1′) of patterning the second electrically conductive film by using a mask covering the global line region to remove a portion of the second electrically conductive film that is located in the local line region, and step (e2′), performed after step (e1′), of patterning the first electrically conductive film and the second electrically conductive film to form the lower layer from the first electrically conductive film and the upper layer from the second electrically conductive film.

In one embodiment, step (e2′) comprises a step of patterning the first electrically conductive film and the second electrically conductive film through a photolithography process using a gradation mask.

In one embodiment, the semiconductor layer is an oxide semiconductor layer.

In one embodiment, the oxide semiconductor layer comprises an In—Ga—Zn—O type oxide.

A display device according to an embodiment of the present invention comprises any of the above semiconductor devices and a display medium layer.

### Advantageous Effects of Invention

According to an embodiment of the present invention, in a semiconductor device having a plurality of thin film transistors of a bottom gate structure, it is possible to suppress deteriorations in the thin film transistor characteristics that are caused by a decreased covering ability of a dielectric protection layer (passivation film) that covers the thin film transistors, while avoiding degradations in circuit performance due to an increased wiring resistance.

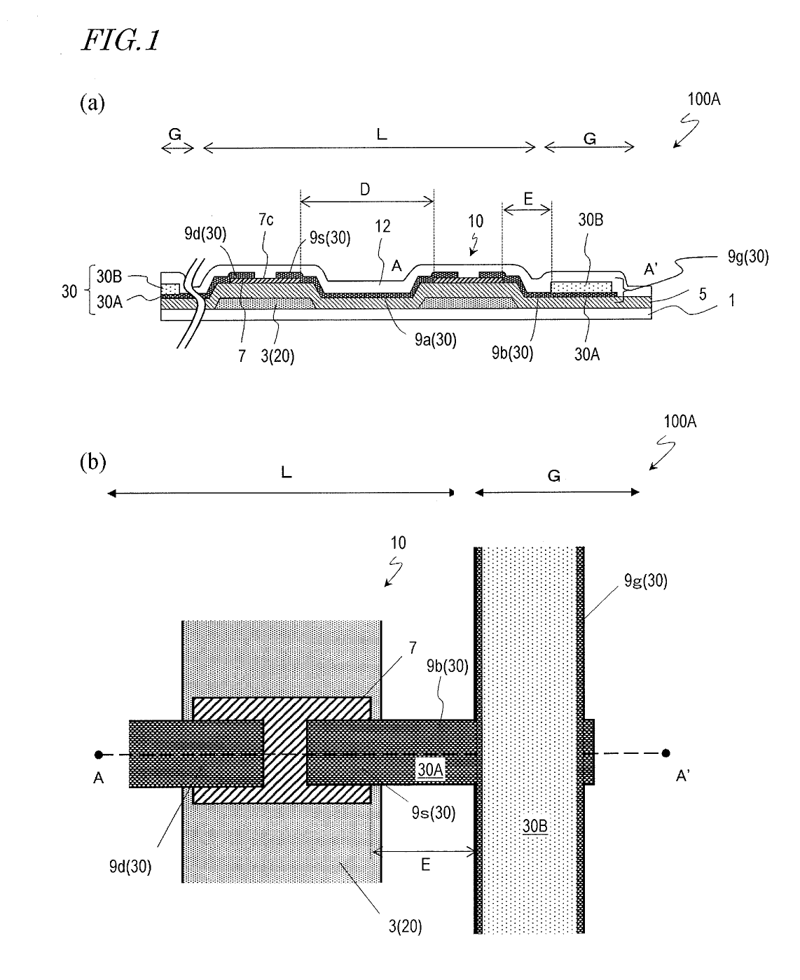

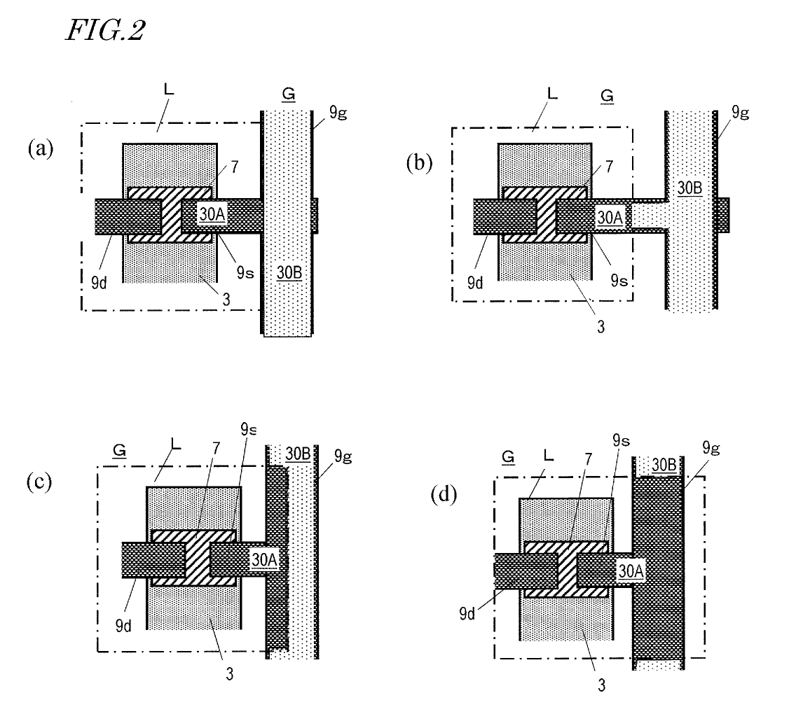

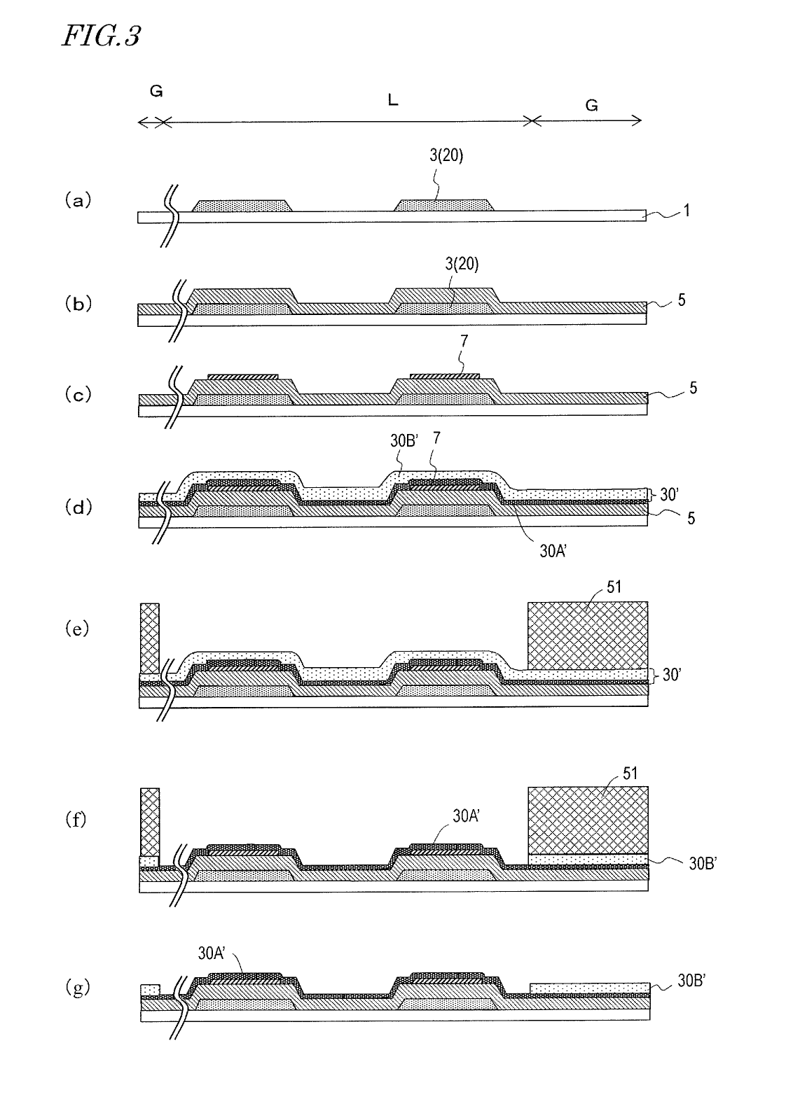

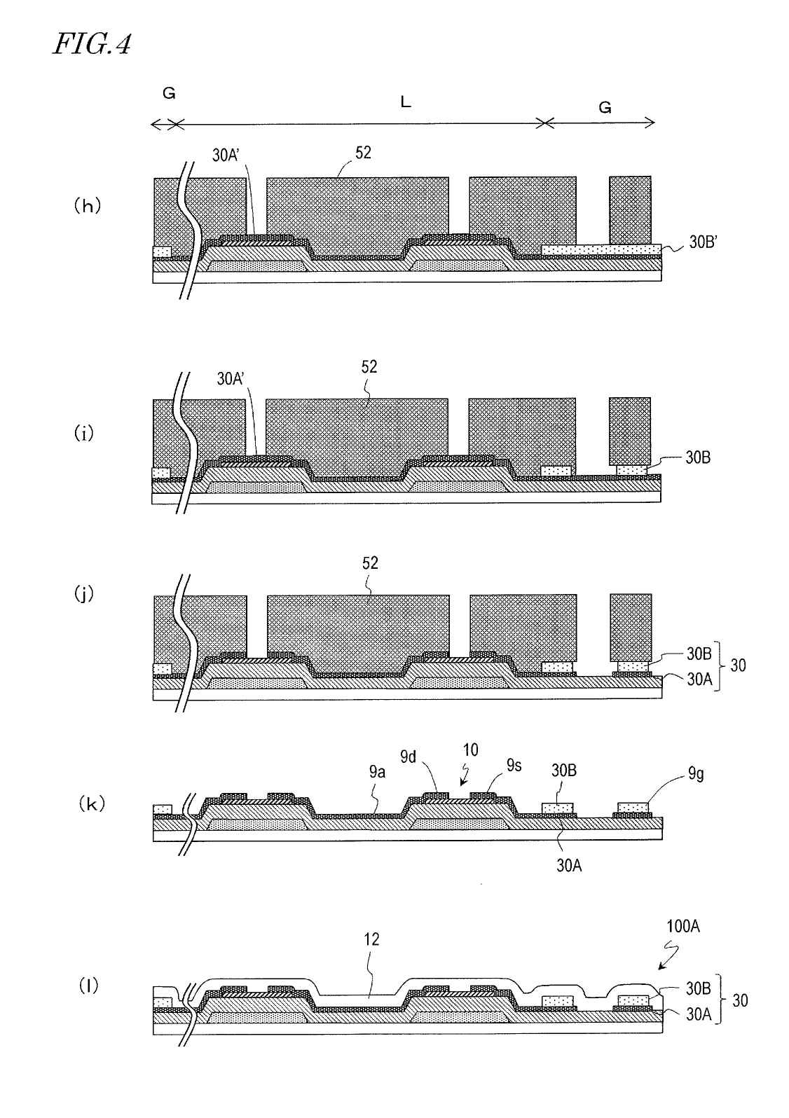

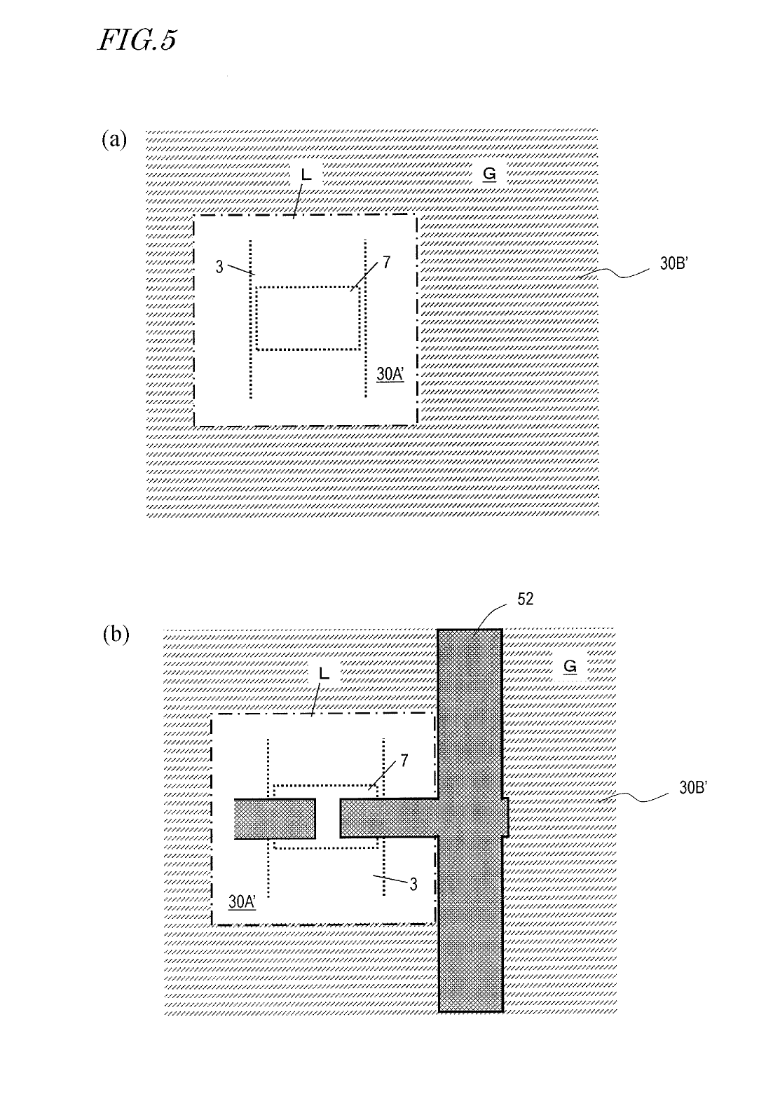

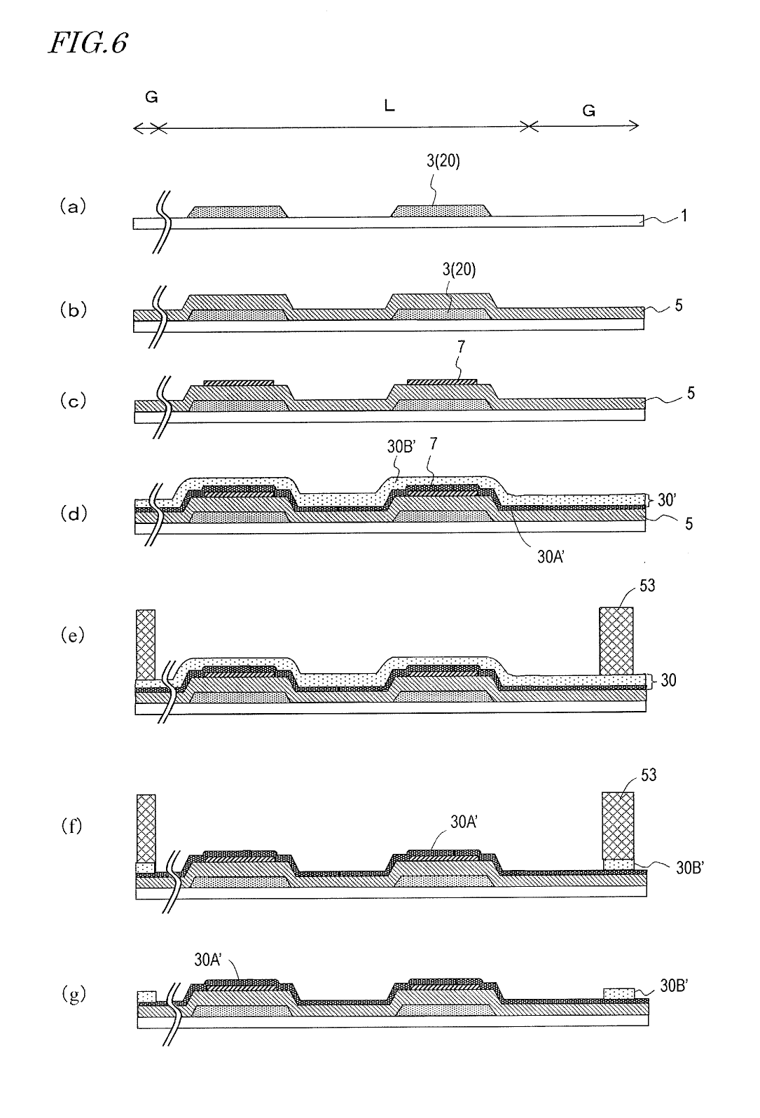

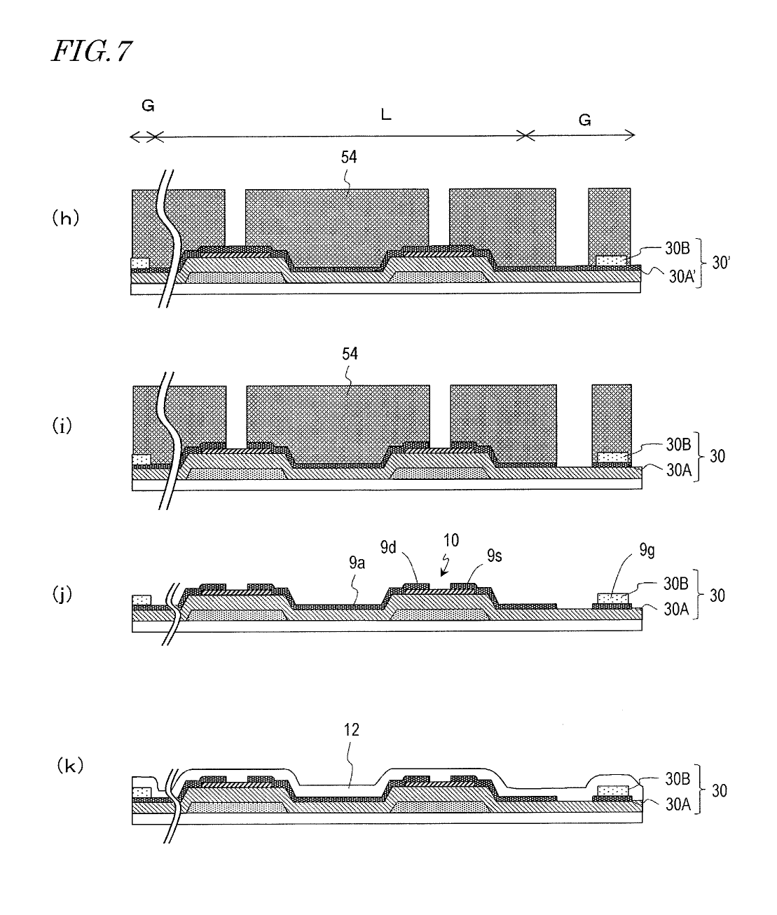

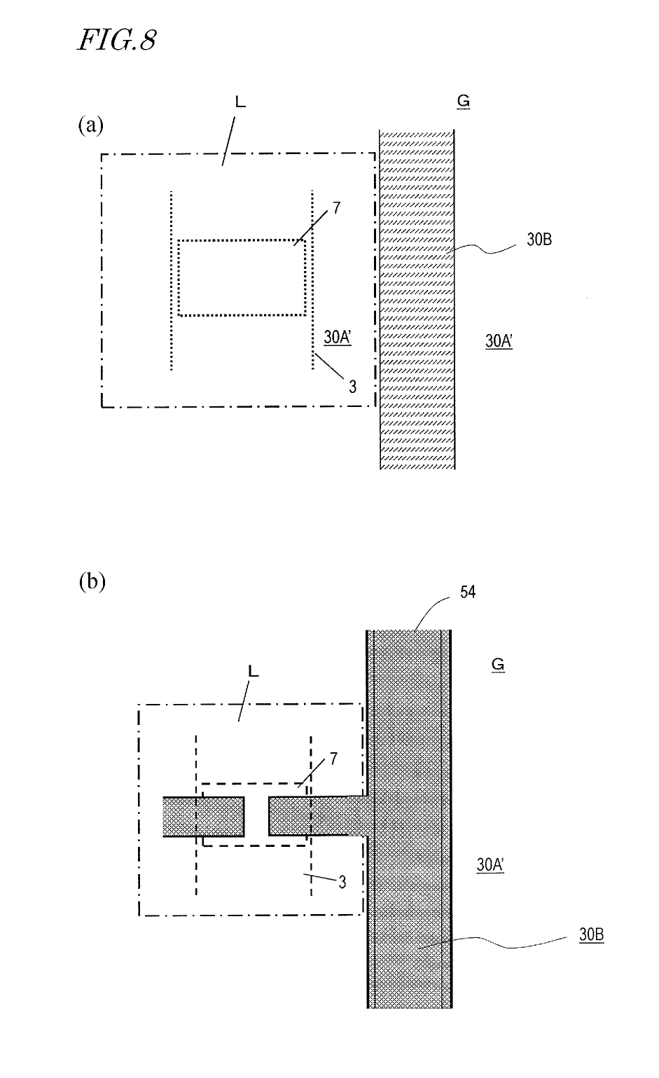

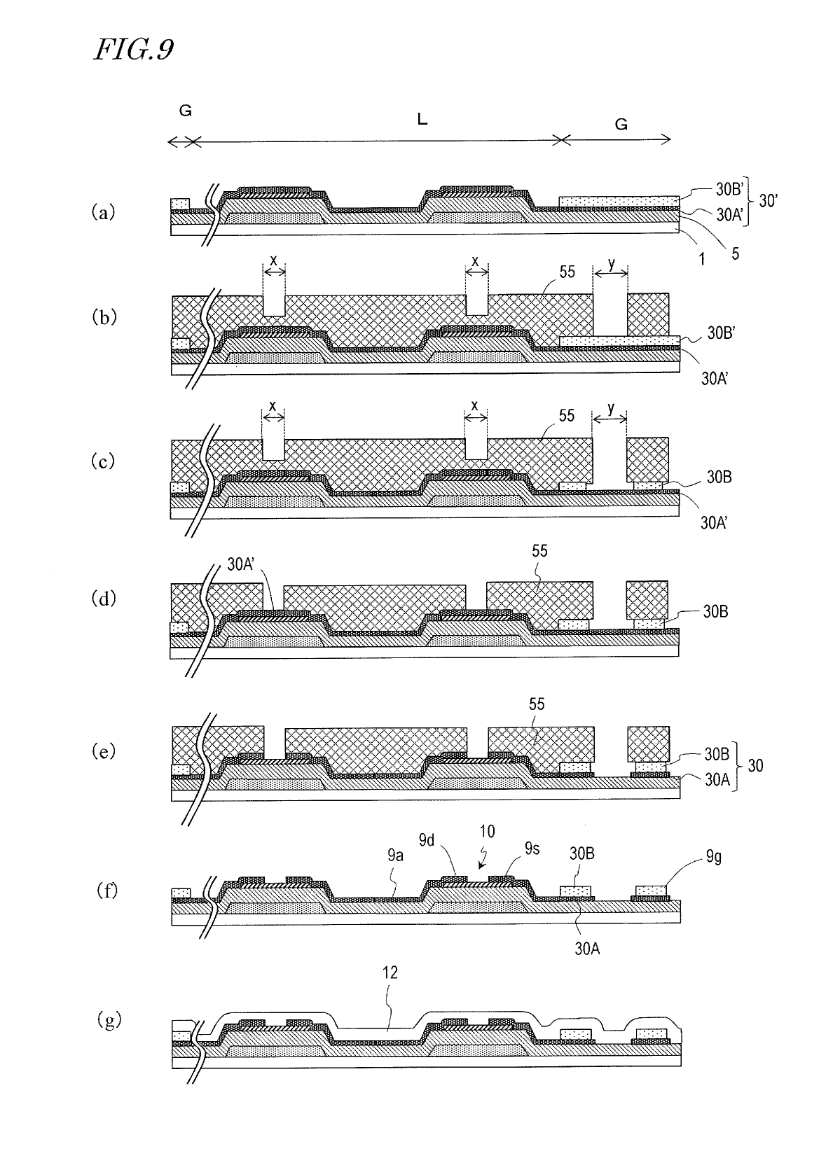

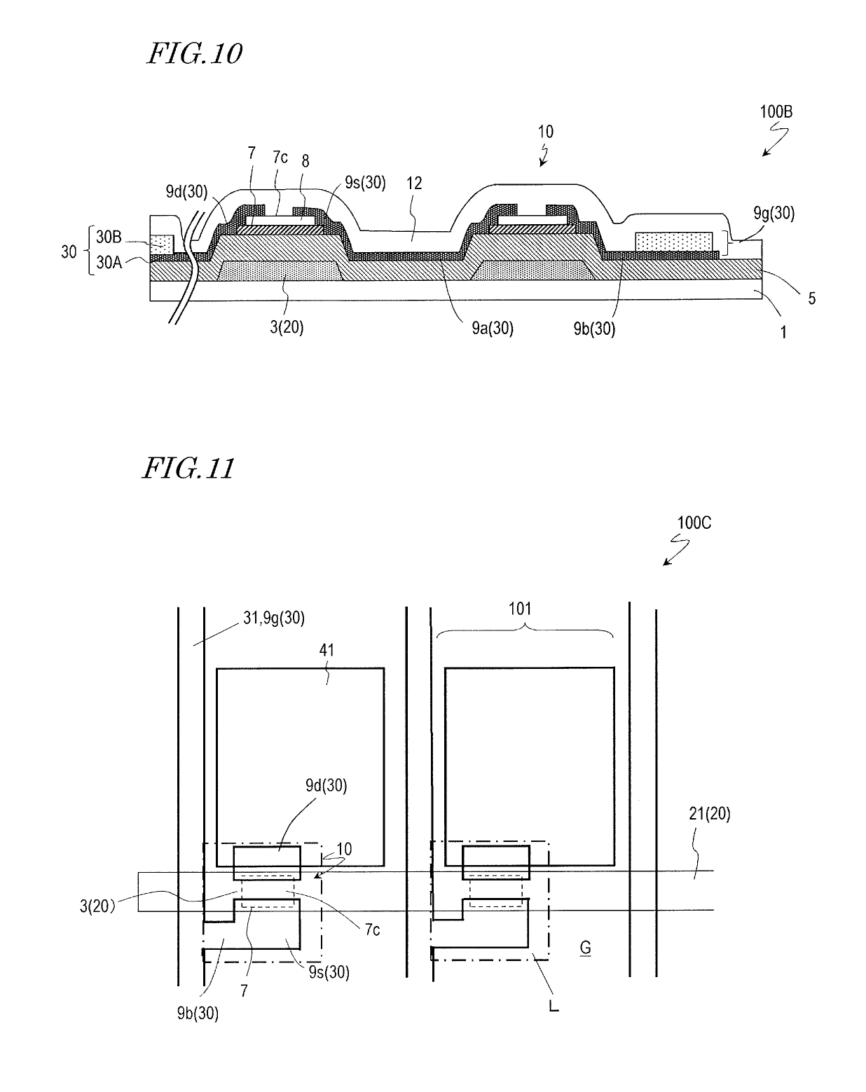

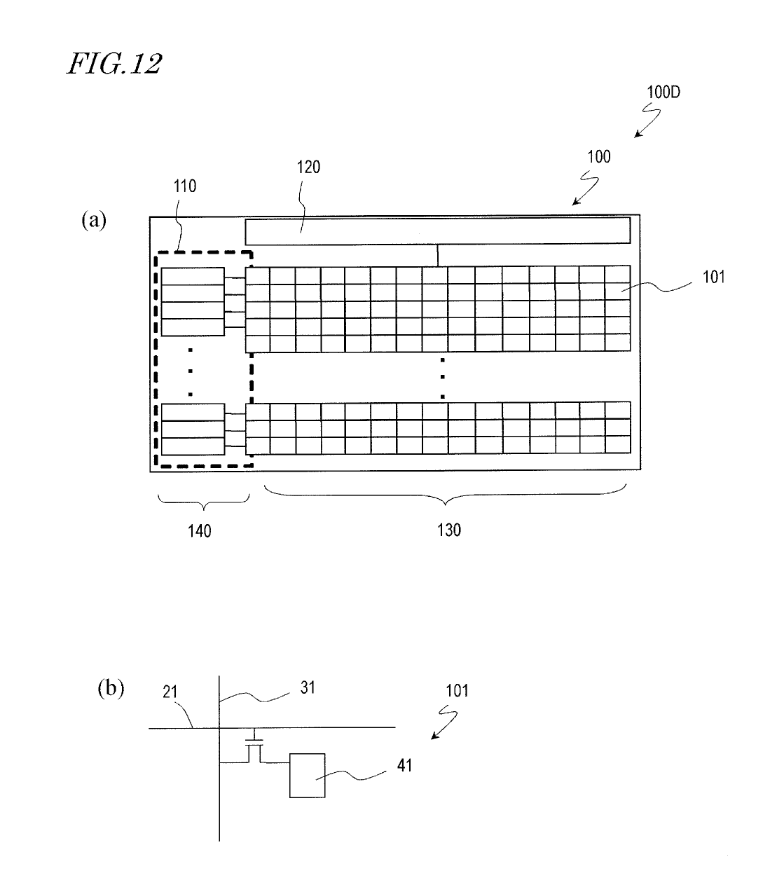

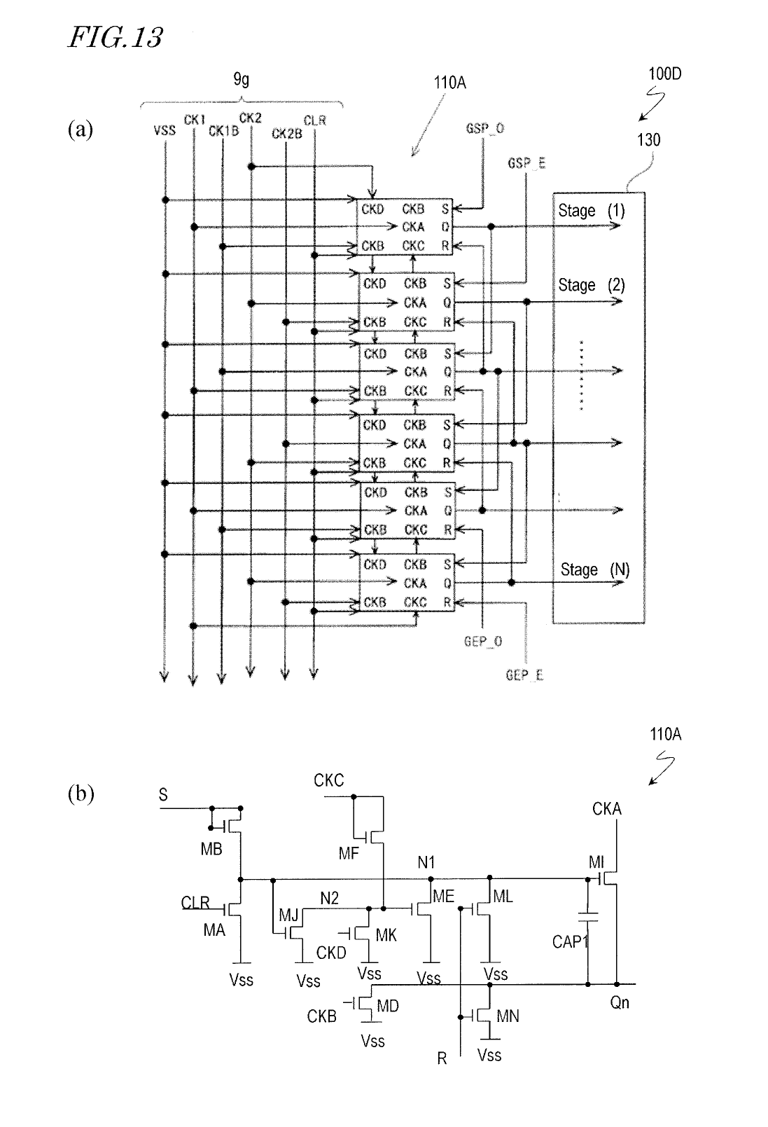

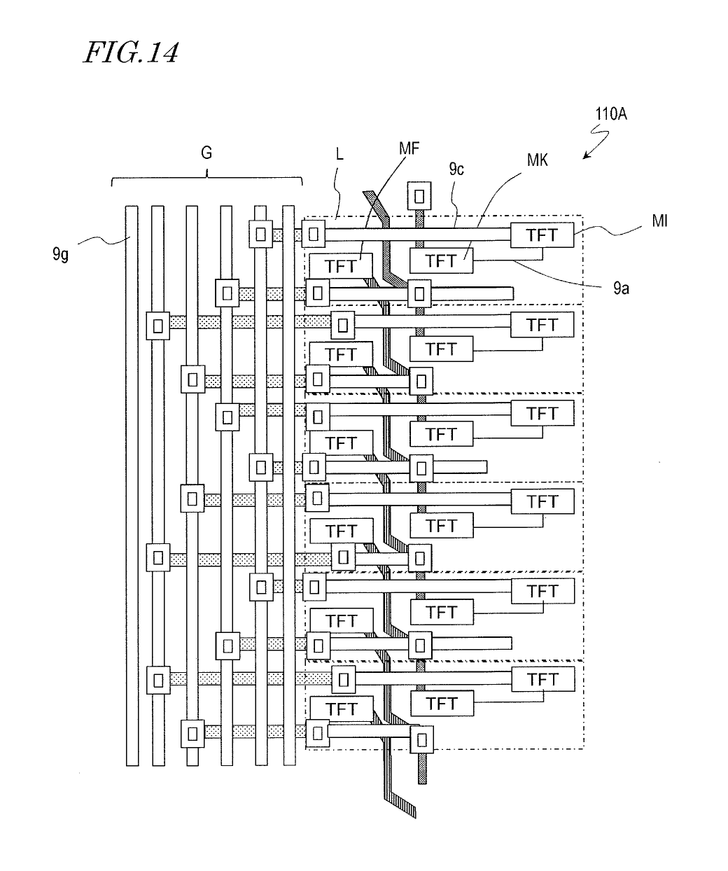

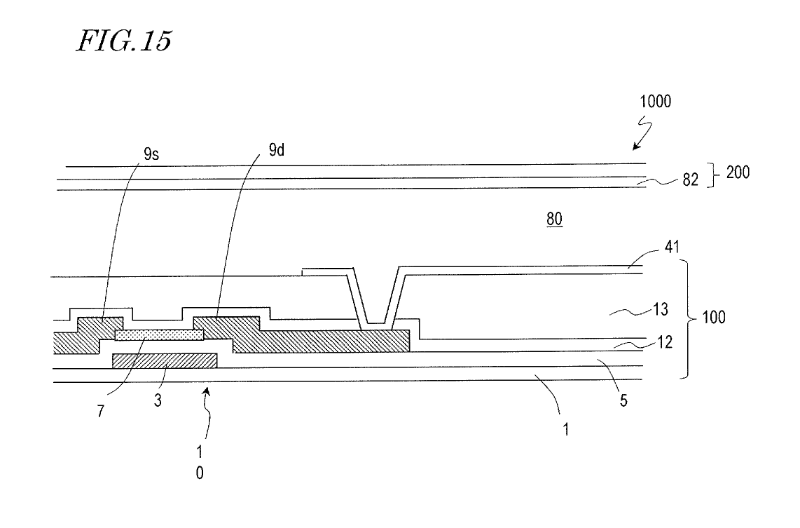

### BRIEF DESCRIPTION OF DRAWINGS

[FIG. 1](a) and (b) are a cross-sectional view and a plan view, respectively, showing a semiconductor device 100A according to a first embodiment of the present invention.

[FIG. 2] Each of (a) to (d) is a plan view illustrating an exemplary arrangement of a global line region G and a local line region L in the semiconductor device 100A according to the present embodiment.

[FIG. 3](a) to (g) are cross-sectional views for describing an exemplary production method for the semiconductor device 100A according to an embodiment of the present invention.

[FIG. 4](h) to (l) are cross-sectional views for describing an exemplary production method for the semiconductor device 100A according to an embodiment of the present invention.

[FIG. 5](a) and (b) are plan views for describing an exemplary production method for the semiconductor device 100A according to an embodiment of the present invention, respectively corresponding to FIG. 3(g) and FIG. 4(h).

[FIG. 6](a) to (g) are cross-sectional views for describing another exemplary production method for the semiconductor device 100A according to an embodiment of the present invention.

[FIG. 7](h) to (k) are cross-sectional views for describing another exemplary production method for the semiconductor device 100A according to an embodiment of the present invention.

[FIG. 8](a) and (b) are plan views for describing an exemplary production method for the semiconductor device 100A according to an embodiment of the present invention, respectively corresponding to FIG. 6(g) and FIG. 7(h).

[FIG. 9](a) to (g) are cross-sectional views for describing still another exemplary production method for the semiconductor device 100A according to an embodiment of the present invention.

[FIG. 10] A cross-sectional view showing a semiconductor device 100B according to a second embodiment of the present invention.

[FIG. 11] A cross-sectional view showing a semiconductor device 100C according to a third embodiment of the present invention.

[FIG. 12](a) is a plan view showing a semiconductor device 100D according to a fourth embodiment of the present invention; and (b) is a diagram for describing the construction of each pixel 101 of the semiconductor device 100D.

[FIG. 13](a) is a block diagram showing the construction of a shift register 110A in a gate driver circuit of the semiconductor device 100D; and (b) is a diagram illustrating an exemplary circuit construction of each stage of the shift register 110A.

[FIG. 14] A diagram for describing a layout for the shift register 110A.

[FIG. 15] A cross-sectional view illustrating an exemplary display device 1000 according to an embodiment of the present invention.

### DESCRIPTION OF EMBODIMENTS

### First Embodiment

With reference to FIG. 1, a semiconductor device 100A according to a first embodiment of the present invention will be described. The semiconductor device 100A illustrated herein is a TFT substrate having a plurality of TFTs on a substrate. The TFT substrate may be used for a display device such as a liquid crystal display device or an organic EL display device, for example. So long as the semiconductor device 100A of the present embodiment includes a plurality of TFTs, there is no limitation to a TFT substrate.

FIGS. 1(a) and (b) are a cross-sectional view and a plan view, respectively, showing a portion of the semiconductor device 100A.

The semiconductor device 100A includes a substrate 1, a plurality of TFTs 10 supported on the substrate 1, global lines 9g, a gate metal layer 20 which includes gate electrodes 3 of the TFTs 10, a source metal layer 30 which includes source and drain electrodes 9s, 9d of the TFTs 10 and global lines 9g, and a dielectric protection layer 12 covering the TFTs 10 and the source metal layer 30. In the present specification, a “global line 9g” refers to a line which supplies a signal that is common to plural TFTs 10.

The semiconductor device (TFT substrate) 100A has a display region which includes a plurality of pixels. For each pixel, a TFT (pixel TFT) is provided as a switching element. A part or a whole of driving circuitry, e.g., drivers, may be provided on the TFT substrate (for a monolithic configuration). The driving circuitry is to be formed in the region (non-display region) of the TFT substrate other than the display region. In the semiconductor device 100A, the TFTs 10 shown in FIG. 1 may be provided in a manner of one for each pixel, as a pixel TFT. In that case, the global lines 9g may be source bus lines. Alternatively, the TFTs 10 may be provided in the non-display region as TFTs composing some circuitry such as shift registers (circuitry TFTs), and the global lines 9g may be lines composing some circuitry (e.g., trunk lines). Furthermore, both the pixel TFTs and the circuitry TFTs may be TFTs 10. The more specific construction of the semiconductor device 100A will be described later.

As shown in FIG. 1(a), each TFT 10 has a bottom gate structure. The TFT 10 has a gate electrode 3, a gate dielectric layer 5 formed on the gate electrode 3, a semiconductor layer 7 formed on the gate dielectric layer 5, and a source electrode 9s and a drain electrode 9d which are provided on the semiconductor layer 7 and electrically connected to the semiconductor layer 7. In this example, the source electrode 9s and the drain electrode 9d are formed so as to be in contact with portions of the upper face of the semiconductor layer 7 that are on both sides of a channel region 7c. The surface of the channel region 7c is in contact with the dielectric protection layer 12. Moreover, when viewed from the normal direction of the substrate 1, at least the channel region 7c of the semiconductor layer 7 overlaps the gate electrode 3, via the gate dielectric layer 5.

Each global line 9g is electrically connected to plural TFTs 10. In this example, the global lines 9g are formed so as to be integral with the source electrodes 9s of the TFTs 10.

The gate metal layer 20 refers to a layer that encompasses electrodes, wiring lines such as gate bus lines, terminals, and the like which are formed by patterning an electrically conductive film that composes the gate electrodes 3 of the TFTs 10. In addition to the gate electrodes 3 and gate bus lines, the gate metal layer 20 may also include CS bus lines, CS electrodes, and the like not shown.

The source metal layer 30 refers to a layer that encompasses electrodes, wiring lines such as source bus lines, terminals, and the like which are formed by patterning an electrically conductive film that composes the source electrodes 9s and the drain electrodes 9d. In addition to the source electrodes 9s, drain electrodes 9d, and source bus lines, the source metal layer 30 may also include, for example, drain lead lines/electrodes (line/electrodes which oppose CS bus lines or CS electrodes so as to form CS capacitors) and the like, which are not shown. It may also include lines composing driving circuitry and electrodes of circuit elements. Herein, the source metal layer 30 includes the source electrodes 9s, the drain electrodes 9d, and the global lines 9g. In addition, it may also include: inter-transistor connection lines 9a each connecting two TFTs 10; global line-transistor connection lines 9b connecting the global lines 9g and the TFTs 10; and so on.

The source metal layer 30 according to the present embodiment includes a lower layer 30A and an upper layer 30B stacked on a portion of the lower layer 30A. Therefore, the source metal layer 30 includes portions that include the lower layer 30A and the upper layer 30B, and portions that include the lower layer 30A but no upper layer 30B. In the present specification, a wiring structure that includes the lower layer 30A and the upper layer 30B is referred to as a “first layer structure”, whereas a wiring structure that includes the lower layer 30A but no upper layer 30B is referred to as a “second layer structure”. The lower layer 30A and the upper layer 30B may each be a single layer, or have a multilayer structure of two or more layers. The surface of the upper layer 30B in the first layer structure may be in contact with the dielectric protection layer 12, and the surface of the lower layer 30A in the second layer structure may be in contact with the dielectric protection layer 12.

Each global line 9g according to the present embodiment has the first layer structure. On the other hand, at least the portions of each source electrode 9s and each drain electrode 9d that are located over the semiconductor layer 7 of the TFT 10 have the second layer structure. In the example shown, at least the portions of the source electrode 9s and the drain electrode 9d that are located over the semiconductor layer 7 of the TFT 10 are composed only of the lower layer 30A, whereas the global line 9g is composed of the lower layer 30A and upper layer 30B. Therefore, the dielectric protection layer 12 is in contact with the lower layer 30A above the semiconductor layer 7, while the upper layer 30B of each global line 9g is in contact with the dielectric protection layer 12.

In the case where the semiconductor device 100A has three or more TFTs, at least two TFTs among them may have the aforementioned construction. In the semiconductor device 100A, at least a part of the lines which supply common signals to plural TFTs 10 may have the aforementioned wiring structure.

According to the present embodiment, in the source metal layer 30, the thickness and material of the global lines 9g and the thickness and material of the source electrodes 9s and drain electrodes 9d on the semiconductor layer 7 can be controlled independently of each other. Therefore, while keeping the resistance of the global lines 9g low, the covering ability of the dielectric protection layer 12 with respect to the TFTs 10 can be improved. Hereinafter, advantages of the present embodiment will be described in detail.

In the present embodiment, the structure of the source metal layer 30 may be varied in parts. This makes it possible to individually optimize the structure of electrodes, lines, and the like in the source metal layer 30 in accordance with their purposes, the positions at which they are formed, and so on.

Moreover, the source electrodes 9s and the drain electrodes 9d on the semiconductor layer 7 can be made thinner than the global lines 9g. As a result of this, while keeping the resistance of the global lines 9g low, it is possible to suppress decreases in covering ability, e.g., voids occurring in the dielectric protection layer 12 due to stepped portions of the source electrodes 9s and drain electrodes 9d. Consequently, degradation in the TFT characteristics, as caused by intrusion of impurities and moisture into the semiconductor layer 7, can be suppressed.

In the example shown, the width of each gate electrode 3 along the channel length direction is larger than the width of the semiconductor layer 7 along the channel length direction. In such a case, when viewed from the normal direction of the surface of the substrate 1, at least the portions of each source electrode 9s and each drain electrode 9d that overlap the gate electrode 3 may have the second layer structure. This allows for a more effective suppression of fluctuations in the electrical characteristics, etc., of the semiconductor layer 7 due to a decreased covering ability of the dielectric protection layer 12.

Furthermore, since the thickness of the source electrodes 9s and drain electrodes 9d and the thickness of the global lines 9g can be separately controlled, it is possible to make the thickness of the global lines 9g greater than conventional, without increasing the thickness of the source electrodes 9s and the drain electrodes 9d on the semiconductor layer 7. Thus, while maintaining the covering ability of the dielectric protection layer 12, the wiring resistance can be further reduced, thereby improving the circuit performance.

The source electrode 9s and the drain electrode 9d of each TFT 10 may be composed only of the lower layer 30A, and thus the upper layer 30B does not need to compose the TFT 10. In this case, the lower layer 30A may be allowed to extend to the exterior of the TFT 10 (i.e., outside of the semiconductor layer 7 and its neighboring region of the TFT 10) so as to be utilized for connection with another TFT or line. This allows for a more effective suppression of deteriorations in the TFTs 10 due to a decreased covering ability of the dielectric protection layer 12. Note that the source electrode 9s may refer to a portion of the source metal layer 30 which overlaps the semiconductor layer 7 when viewed from the normal direction of the substrate 1 and which functions as a source of the TFT 10, whereas the drain electrode 9d may refer to a portion of the source metal layer 30 which overlaps the semiconductor layer 7 when viewed from the normal direction of the substrate 1 and which functions as a drain of the TFT 10. In this case, the aforementioned “exterior of the TFT 10” refers to a region other than the region (TFT region) that is defined by the semiconductor layer 7, the source electrode 9s, and the drain electrode 9d as viewed from the normal direction of the substrate 1.

In the example shown, TFTs of channel-etch structure are used as the TFTs 10. Generally speaking, a process of forming TFTs of channel-etch structure has a problem in that the channel regions in the semiconductor layer are likely to be damaged in the etching step for forming the source and drain electrodes. In the etching step, for example, an electrically conductive film is deposited on the surface of the semiconductor layer, and this electrically conductive film is subjected to an anisotropic etching, whereby the source electrodes and the drain electrodes become separated. At this point, variations in the thickness of the electrically conductive film will be greater as the electrically conductive film becomes thicker, thus allowing an increasing amount (overetching amount) to be removed through anisotropic etching from the portions to become the channel regions in the semiconductor layer. Note that an “overetching amount” is the amount of etching received by a semiconductor material that is the underlying material of an electrically conductive material which was earlier removed as the material to be etched. As the overetching amount increases, the damage received by the semiconductor layer also increases, so that stable TFT characteristics may not be obtained. In particular, when an oxide semiconductor layer is used as the semiconductor layer, there is a significant characteristics deterioration due to the damage incurred at the etching step. On the other hand, according to the present embodiment, the electrically conductive film formed on the semiconductor layer 7 can be made thinner than conventional, whereby the overetching amount of the semiconductor layer 7 can be kept small at the etching step for forming the source electrodes 9s and the drain electrodes 9d. Therefore, damage to the semiconductor layer 7 can be reduced, whereby degradation in the TFT characteristics can be suppressed.

The thickness of the source electrodes 9s and the drain electrodes 9d on the semiconductor layer 7, i.e., the thickness t_{A} of the lower layer 30A is e.g. 200 nm or less, and more preferably 100 nm or less. As a result of this, decrease in the covering ability of the dielectric protection layer 12 can be suppressed better. Moreover, damage to the semiconductor layer 7 through anisotropic etching can be reduced more effectively. On the other hand, if the thickness t_{A} of the lower layer 30A is e.g. 300 nm or more, the TFT resistance can be kept smaller.

The thickness of the global lines 9g, i.e., the total thickness t_{B} of the lower layer 30A and the upper layer 30B, is e.g. 300 nm or more, and more preferably 400 nm or more. As a result of this, the resistance of the global lines 9g can be kept even lower, so that the operating speed of circuitry that contains the TFTs 10 can be enhanced more effectively. On the other hand, from processability and other standpoints, it is preferable that the thickness t_{B} is 500 nm or less.

Note that the thickness of the lower layer 30A in the first layer structure and the thickness of the lower layer 30A in the second layer structure are substantially equal. However, when etching the upper layer 30B to remove it, the surface layer of the lower layer 30A may also become removed in some cases. In those cases, the lower layer 30A in the first layer structure will be thicker than the lower layer 30A in the second layer structure.

The lower layer 30A may be thinner than the upper layer 30B. This more effectively ensures reduction in the resistance of the global lines 9g and a suppression of degradation in the TFT characteristics. The thickness of the upper layer 30B may be not less than twice as much and not more than 10 times as much as the thickness of the lower layer 30A, for example.

In the example shown, the inter-transistor connection lines 9a and the global line-transistor connection lines 9b both have the second layer structure. Note that the connection lines 9a and 9b may partially have the first layer structure. The wiring structure of the connection lines 9a and 9b may be appropriately chosen in accordance with the distance with the TFT 10 that is located the closest thereto.

When the inter-transistor connection lines 9a have the second layer structure, there is no need to partially form the upper layer 30B between adjoining TFTs 10. Thus, it is not necessary to increase the distance D between adjoining TFTs 10 so as to account for a design margin associated with lithography; therefore, the distance D between adjoining TFTs 10 can be made smaller than in the case where the inter-transistor connection lines 9a have the first layer structure. As used herein, the distance D refers to the shortest distance between two portions of the semiconductor layer 7 as viewed from the normal direction of the surface of the substrate 1.

In the region containing the semiconductor layer 7 and its neighborhood, it is preferable that the source metal layer 30 has the second layer structure. If any portion of the source metal layer 30 that has the first layer structure is provided in the neighborhood of the semiconductor layer 7, the covering ability of the dielectric protection layer 12 may be decreased by a stepped portion emerging at the edge of the upper layer 30B, so that moisture or the like may intrude into the semiconductor layer 7. Assuming a shortest distance E between the semiconductor layer 7 and the edge of the upper layer 30B as viewed from the normal direction of the surface of the substrate 1, the distance E is 3 μm or more, and more preferably 10 μm or more, for example. Note that the distance E may be appropriately chosen in accordance with the process margin, the thickness of the upper layer 30B, the material of the dielectric protection layer 12, and so on. In the present embodiment, the upper layer 30B is in a region which is sufficiently distant from the TFT 10 so as to reduce the influence of the stepped portion due to the semiconductor layer 7 and the gate electrode 3, e.g., the region where the surface of the gate dielectric layer 5 has become substantially flat. This more effectively restrains moisture and the like from intruding into the semiconductor layer 7.

The lower layer 30A may include a first layer, whereas the upper layer 30B may include a second layer which is formed on the first layer by using a different material from that of the first layer. As a result, patterning for forming the lower layer 30A and upper layer 30B can be performed by utilizing an etching rate difference. The lower layer 30A may be composed only of the first layer, or may further include another layer on the lower side (the substrate side) of the first layer. Similarly, the upper layer 30B may be composed only of the second layer, or may further include another layer on the second layer.

The semiconductor device 100A of the present embodiment may have global line regions G containing the global lines 9g and local line regions L containing the TFTs 10, such that any portion of the source metal layer 30 that is located within a global line region G has the first layer structure and that any portion of the source metal layer 30 that is located within a local line region L has the second layer structure. Each local line region L is located in a region containing a TFT 10 and its neighborhood, whereas each global line region G is located in a region other than the TFT 10 and its neighborhood. Each region in which plural TFTs 10 are located in proximity may define a local line region L, whereas each region located between plural local line regions L may define a global line region G.

When viewed from the normal direction of the surface of the substrate 1, it is preferable that each global line region G is distant by e.g. 5 μm or more from the semiconductor layer 7 of the TFT 10 that is located the closest thereto. Thus, by restricting the thick portions of the source metal layer 30 having the first layer structure to be within the global line regions G, a sufficient distance can be ensured between the semiconductor layer 7 of each TFT and the edge of the upper layer 30B in the substrate plane; as a result, a decrease in the covering ability of the dielectric protection layer 12 in the neighborhood of the semiconductor layer 7 can be better suppressed.

The exact arrangement of the local line regions L and the global line regions G may be appropriately chosen in accordance with the construction of circuitry that contains the TFTs 10, the distance between the semiconductor layer 7 of each TFT 10 and each global line 9g, and so on. With respect to an exemplary case where the source metal layer 30 has the pattern shown in FIG. 1(b), each local line region L may be arranged to contain the entire line (protrusion) that protrudes from the global line 9g, as shown in FIG. 2(a), when viewed from the normal direction of the substrate 1. Alternatively, as shown in FIG. 2(b), each local line region L may be arranged to contain only a portion of the protrusion. In this case, the portion of the protrusion that is close to the global line 9g has the first layer structure, whereas its portion that is close to the TFT 10 has the second layer structure. In the case where the global line 9g and the TFT 10 are relatively close, as shown in FIG. 2(c), each local line region L may be arranged to contain a portion of the global line 9g. Furthermore, as shown in FIG. 2(d), each local line region L may be arranged to traverse the global line 9g (e.g., a source bus line). In this case, the upper layer 30B is partitioned upon the global line 9g, such that the partitioned portion of the upper layer 30B is composed only of the lower layer 30A. Note that the global line region G and the local line region L may be arranged to partially overlap each other.

<Production Method of the Semiconductor Device 100A>

Next, with reference to FIG. 3 to FIG. 5, an exemplary production method for the semiconductor device 100A will be described.

FIGS. 3(a) to (g) and FIGS. 4(h) to (l) are step-by-step cross-sectional views for describing a production method for the semiconductor device 100A. FIGS. 5(a) and (b) are plan views respectively corresponding to FIG. 3(g) and FIG. 4(h).

First, as shown in FIG. 3(a), a gate metal layer 20 including gate electrodes 3, gate bus lines (not shown) and connection lines (not shown) is formed on a substrate 1 such as a glass substrate. The gate metal layer 20 is formed by forming an electrically conductive film for gates (not shown) on the substrate 1 by using a sputtering technique, and patterning the electrically conductive film for gates by using a mask.

The substrate 1 is typically a transparent substrate, e.g., a glass substrate. Other than a glass substrate, a plastic substrate may also be used. The plastic substrate may be a substrate made of a thermosetting resin or a thermoplastic resin, or a composite substrate of any such resin and an inorganic fiber (e.g., a glass fiber, a nonwoven fabric of glass fiber). As a thermally resistant resin material, polyethylene terephthalate (PET), polyethylene naphthalate (PEN), polyether sulfone (PES), acrylic resins, or polyimide resins can be used.

As the material of the gate metal layer 20, a metal such as aluminum (Al), molybdenum (Mo), copper (Cu), or titanium (Ti), an alloy containing at least one of them, or a metal nitride thereof can be used. Herein, as the electrically conductive film for gates, a Ti/Al/Ti film (thickness: e.g. not less than 100 nm and not more than 500 nm) is used, for example.

Then, as shown in FIG. 3(b), a gate dielectric layer 5 is formed so as to cover the gate metal layer 20. The gate dielectric layer 5 is formed by using a CVD technique, for example. As the material of the gate dielectric layer 5, for example, silicon oxide (SiOₓ), silicon nitride (SiNₓ), silicon oxynitride (SiOₓN_{y}, x>y), or silicon nitroxide (SiNₓO_{y}, x>y) can be used. The gate dielectric layer 5 may be a single-layer film, or a multilayer film. Herein, the gate dielectric layer 5 is an SiO₂ film having a thickness of not less than 100 nm and not more than 500 nm, for example.

Then, as shown in FIG. 3(c), a semiconductor layer 7 is formed in island shapes. Specifically, first, an oxide semiconductor film (not shown) is formed on the gate dielectric layer 5 by using a sputtering technique. Herein, as the oxide semiconductor film, an In—Ga—Zn—O type oxide semiconductor film having a thickness of not less than 30 nm and not more than 300 nm is formed, for example. Thereafter, the oxide semiconductor film is patterned by photolithography to give a semiconductor layer (which herein is an oxide semiconductor layer) 7 in island shapes.

The oxide semiconductor film and the semiconductor layer 7 contain an In—Ga—Zn—O type semiconductor, for example. Herein, the In—Ga—Zn—O type semiconductor is a ternary oxide of In (indium), Ga (gallium), and Zn (zinc). The ratio between In, Ga, and Zn (composition ratio) is not particularly limited, and includes In:Ga:Zn=2:2:1, In:Ga:Zn=1:1:1, In:Ga:Zn=1:1:2, and the like, for example. The In—Ga—Zn—O type semiconductor may be amorphous or crystalline. As a crystalline In—Ga—Zn—O type semiconductor, a crystalline In—Ga—Zn—O type semiconductor whose c axis is oriented generally perpendicular to the layer plane is preferable. The crystal structure of such an In—Ga—Zn—O type semiconductor is disclosed in Japanese Laid-Open Patent Publication No. 2012-134475, for example. The entire disclosure of Japanese Laid-Open Patent Publication No. 2012-134475 is incorporated herein by reference.

As the material of the oxide semiconductor film, oxide semiconductors other than In—Ga—Zn—O type semiconductors may be used, e.g., InGaO₃(ZnO)₅, magnesium zinc oxide (MgₓZn₁₋ₓO), cadmium zinc oxide (CdₓZn₁₋ₓO), and cadmium oxide (CdO). Moreover, ZnO in an amorphous state, a polycrystalline state, or a microcrystalline state including a mixture of an amorphous state and a polycrystalline state, to which one or more impurity elements among group-1 elements, group-13 elements, group-14 elements, group-15 elements, group-17 elements or the like has been added, may be used; or those to which no impurity element has been added may also be used. Alternatively, another semiconductor film (a silicon semiconductor film or the like) may be used instead of an oxide semiconductor film.

Thereafter, as shown in FIG. 3(d), by e.g. a sputtering technique, a first electrically conductive film 30A′ and a second electrically conductive film 30B′ are formed on the gate dielectric layer 5 and the semiconductor layer 7 in this order, thus forming an electrically conductive film 30′ for sources that has a multilayer structure (which herein is a two-layer structure). As the material of the first electrically conductive film 30A′ and the second electrically conductive film 30B′, for example, a film containing a metal such as aluminum (Al), tungsten (W), molybdenum (Mo), tantalum (Ta), copper (Cu), chromium (Cr), or titanium (Ti), or an alloy or a metal nitride thereof, may be used as appropriate. Each electrically conductive film 30A′, 30B′ may be a single-layer film, or a multilayer film.

As the material of the first electrically conductive film 30A′, a material which exhibits a lower etching rate while etching the second electrically conductive film 30B′ than that of the material of the second electrically conductive film 30B′ may be used, thereby making it easy to only pattern the second electrically conductive film 30B′. Moreover, the thickness of the first electrically conductive film 30A′ may be smaller than the thickness of the second electrically conductive film 30B′; this allows the portions of the source metal layer that have the first layer structure to be made thinner. Furthermore, the sheet resistance of the second electrically conductive film 30B′ may be lower than the sheet resistance of the first electrically conductive film 30A′; this allows for a lower resistance of the global lines, thus improving the circuit characteristics. The first electrically conductive film 30A′ contains Ti, W, or Mo. Since Ti and Mo are less likely to act on oxide semiconductors than are other metals (Al, Cu, etc.), degradation in the TFT characteristics due to a metal from the source metal layer 30 acting on the oxide semiconductor layer 7 can be suppressed. The second electrically conductive film 30B′ contains Al or Cu, for example. An Al film or a Cu film has the advantage of relatively low resistance and good processability. Herein, a Ti film with a thickness of not less than 20 and not more than 150 (e.g., 70 nm) is formed as the first electrically conductive film 30A′, and an Al film with a thickness of not less than 100 nm and not more than 500 nm (e.g., 300 nm) is formed as the second electrically conductive film 30B′.

Next, as shown in FIG. 3(e), a first photoresist 51 is formed on the electrically conductive film 30′ for sources by using a first mask. The first photoresist 51 is disposed in a manner of at least covering the portions to become global lines and not covering over the semiconductor layer 7. Herein, the mask data of the first mask is designed so that the regions covered by the first photoresist 51 correspond to global line regions G in which lines and electrodes having the first layer structure are to be formed, and that the regions not covered by the first photoresist 51 correspond to local line regions L in which TFTs and lines and electrodes having the second layer structure are to be formed.

Then, as shown in FIG. 3(f), portions of the second electrically conductive film 30B′ that are not covered by the first photoresist 51 are removed by a dry etching technique or a wet etching technique. Irrespective of whichever etching method is used, the materials and the etching method for these films 30A′ and 30B′ are to be selected so that the etching rate of the first electrically conductive film 30A′ is lower than the etching rate of the second electrically conductive film 30B′. As a result, in the regions not covered by the first photoresist 51, only the second electrically conductive film 30B′ is patterned, whereas the first electrically conductive film 30A′ is hardly etched.

Thereafter, as shown in FIG. 3(g), the first photoresist 51 is removed. A plan view corresponding to FIG. 3(g) is shown in FIG. 5(a). As can be seen from FIG. 3(g) and FIG. 5(a), the second electrically conductive film 30B′ is formed across the global line region G. In the local line regions L, the second electrically conductive film 30B′ is removed, leaving the upper face of the first electrically conductive film 30A′ exposed.

Next, as shown in FIG. 4(h), a second photoresist is formed on the electrically conductive film 30′ for sources, by using a second mask. Herein, the second mask is designed so as to define a pattern of drain electrodes and source electrodes of the TFTs and lines (local lines) such as inter-transistor connection lines in the local line regions L, and define a pattern of lines having the first layer structure, e.g., global lines, in the global line regions G. An exemplary pattern of the second photoresist 52 is illustrated in FIG. 5(b).

Then, as shown in FIG. 4(i), the portions of the second electrically conductive film 30B′ that are not covered by the second photoresist 52 are removed by a dry etching technique or a wet etching technique. Irrespective of whichever etching method is used, the materials and the etching method for these films 30A′ and 30B′ are to be selected so that the etching rate of the first electrically conductive film 30A′ is lower than the etching rate of the second electrically conductive film 30B′. Therefore, even in the regions not covered by the second photoresist 52, only the second electrically conductive film 30B′ is patterned, whereas the first electrically conductive film 30A′ is hardly etched.

As a result, in the global line regions G, the second electrically conductive film 30B′ is patterned so that an upper layer 30B to be used as the global lines is obtained. On the other hand, in the local line regions L, the second electrically conductive film 30B′ was already removed in the previous etching step (FIG. 3(f)), so that the first electrically conductive film 30A′ is exposed in openings of the second photoresist 52. In this etching step, the exposed first electrically conductive film 30A′ is not patterned. Note that the portions of the semiconductor layer to become channel regions are covered by the first electrically conductive film 30A′, so that this etching step is less likely to damage the portions to become channel regions.

Then, as shown in FIG. 4(j), by again using the second photoresist 52 as an etching mask, the portions of the first electrically conductive film 30A′ that are not covered by the second photoresist 52 are etched away. As the etching method, for example, a dry etching technique or a wet etching technique such as an RIE (reactive ion etching) technique is used. As a result, a lower layer 30A is obtained from the first electrically conductive film 30A′. Thus, a source metal layer 30 including the lower layer 30A and upper layer 30B is obtained.

In the present embodiment, source electrodes 9s and drain electrode 9d composed of the lower layer 30A are obtained in the local line regions L, whereby TFTs 10 are fabricated. Furthermore, local lines composed of the lower layer 30A are formed, e.g., inter-transistor connection lines 9a. On the other hand, in the global line regions G, global lines 9g having a multilayer structure (first layer structure) of the lower layer 30A and the upper layer 30B are formed. Thereafter, as shown in FIG. 4(k), the second photoresist 52 is removed.

Then, as shown in FIG. 4(l), by using e.g. a CVD apparatus, a dielectric protection layer (passivation layer) 12 which covers the TFTs 10 and the source metal layer 30 is provided. The dielectric protection layer 12 may be made of SiOₓ, SiNₓ, SiOₓN_{y} (silicon oxynitride, x>y), SiNₓO_{y} (silicon nitroxide, x>y), Al₂O₃ (aluminum oxide), Ta₂O₅ (tantalum oxide), or the like. The thickness of the dielectric protection layer 12 is e.g. not less than 100 nm and not more than 300 nm, although there is no particular limitation. Herein, as the dielectric protection layer 12, an SiO₂ film is formed by a plasma CVD technique.

Thereafter, although not shown, a planarization film may be formed on the dielectric protection layer 12. The planarization film can be obtained by, for example, applying a photo-sensitive organic film on the dielectric protection layer 12 and curing it. In this manner, the semiconductor device 100A is produced.

The above-described method makes it possible to form the drain electrodes 9d and source electrodes 9s of the TFTs 10 only from the first electrically conductive film 30A′, thus reducing the stepped portions occurring in the underlying of the dielectric protection layer 12 in the neighborhood of the TFTs 10. As a result, deteriorations in the covering ability of the dielectric protection layer 12 can be suppressed in the neighborhood of the TFTs 10. Moreover, in the etching step (source/drain isolation step) for forming the source electrodes 9s and the drain electrodes 9d, only the first electrically conductive film 30A′ is patterned, so that the damage on the portions of the semiconductor layer 7 to become channels during patterning can be reduced. In particular, this effect is significant when the first electrically conductive film 30A′ has a small thickness.

Furthermore, in the global line regions G, the thickness of the global lines 9g can be arbitrarily set, independently of the thicknesses of the source electrodes 9s, the drain electrodes 9d, the local lines, and the like. This allows the thickness of the global lines 9g to be increased, thereby realizing low-resistance wiring lines.

The method of producing the semiconductor device 100A of the present embodiment is not limited to the above method. Hereinafter, another exemplary production method for the semiconductor device 100A will be described.

FIGS. 6(a) to (g) and FIGS. 7(h) to (k) are step-by-step cross-sectional views for describing another production method for the semiconductor device 100A. FIGS. 8(a) and (b) are plan views respectively corresponding to FIG. 6(g) and FIG. 7(h). Component elements similar to those in FIG. 3 to FIG. 5 will be denoted by identical reference numerals, and their descriptions will be omitted.

First, as shown in FIGS. 6(a) to (d), a gate metal layer 20 including gate electrodes 3, a gate dielectric layer 5, and island shapes of a semiconductor layer 7 to become an active layer of TFTs are formed on a substrate 1. Then, on the gate dielectric layer 5 and the semiconductor layer 7, a first electrically conductive film 30A′ and a second electrically conductive film 30B′ are formed in this order, thereby forming an electrically conductive film 30′ for sources. The methods of forming these are similar to the methods described above with reference to FIGS. 3(a) to (d). The materials and thicknesses of the respective layers are also similar to the aforementioned materials and thicknesses.

Then, as shown in FIG. 6(e), a third photoresist 53 is formed on the electrically conductive film 30′ for sources by using a third mask. The third photoresist 53 is designed so as to define a pattern of lines having the first layer structure, e.g., the global lines.

Then, as shown in FIG. 6(f), the portions of the second electrically conductive film 30B′ that are not covered by the third photoresist 53 are etched away. The etching method is similar to the method described above with reference to FIG. 3(f). Thus, an upper layer 30B is obtained from the second electrically conductive film 30B′.

Thereafter, as shown in FIG. 6(g), the third photoresist 53 is removed. A plan view corresponding to FIG. 6(g) is shown in FIG. 8(a). As can be seen from FIG. 6(g) and FIG. 8(a), the upper layer 30B is formed in regions where lines having the first layer structure, e.g., global lines, are to be formed, whereas the upper face of the first electrically conductive film 30A′ is exposed in other regions.

Next, as shown in FIG. 7(h), a fourth photoresist is formed on the electrically conductive film 30′ for sources by using a fourth mask. Herein, the fourth mask is designed so as to define a pattern of drain electrodes and source electrodes of the TFTs and lines (local lines) such as inter-transistor connection lines in the local line regions L, and define a pattern of lines having the first layer structure, e.g., global lines, in the global line regions G. An exemplary pattern of the fourth photoresist 54 is illustrated in FIG. 8(b). As shown in the figure, the first electrically conductive film 30A′ is exposed in the openings of the fourth photoresist 54.

Then, as shown in FIG. 7(i), the portions of the first electrically conductive film 30A′ that are not covered by the fourth photoresist 54 are removed by a dry etching technique or a wet etching technique. As a result, a lower layer 30A is obtained from the first electrically conductive film 30A′. Thus, a source metal layer 30 including the lower layer 30A and upper layer 30B is obtained.

In the present embodiment, source electrodes 9s and drain electrode 9d composed of the lower layer 30A are obtained in the local line regions L, whereby TFTs 10 are fabricated. Furthermore, local lines composed of the lower layer 30A are formed, e.g., inter-transistor connection lines 9a. On the other hand, in the global line regions G, global lines 9g having a multilayer structure (first layer structure) of the lower layer 30A and the upper layer 30B are formed. Thereafter, as shown in FIG. 7(j), the second photoresist 52 is removed.

Then, as shown in FIG. 7(k), a dielectric protection layer (passivation layer) 12 which covers the TFTs 10 and the source metal layer 30 is provided. The material, thickness, and method of formation of the dielectric protection layer 12 are identical to the material, thickness, and method of formation described earlier with reference to FIG. 4(l). Thereafter, although not shown, a planarization film may be formed on the dielectric protection layer 12. In this manner, the semiconductor device 100A is produced.

With the above-described production method, too, effects similar to those of the method described above with reference to FIG. 3 to FIG. 5 are obtained.

In the method described earlier with reference to FIG. 3 to FIG. 5, a gradation mask may be used for the second mask. Hereinafter, an example where a halftone mask is used instead of the second mask will be described.

FIGS. 9(a) to (g) are step-by-step cross-sectional views for describing still another exemplary production method for the semiconductor device 100A.

First, as shown in FIG. 9(a), a gate metal layer 20 including gate electrodes 3, a gate dielectric layer 5, a semiconductor layer 7, a first electrically conductive film 30A′, and a second electrically conductive film 30B′ are formed on a substrate 1. Thereafter, by using a first photoresist, the portions of the second electrically conductive film 30B′ that are located in the local line regions L are removed. The methods of forming these layers and the method of etching the second electrically conductive film 30B′ are similar to the methods described above with reference to FIGS. 3(a) to (g). The materials and thicknesses of the respective layers (or films) are also similar to the aforementioned materials and thicknesses.

Then, as shown in FIG. 9(b), a fifth photoresist 55 is formed on the electrically conductive film 30′ for sources by using a fifth mask. Herein, a gradation mask is used as the fifth mask.

By exposing a photoresist film to light using a gradation mask, regions which have been subjected to three different amounts of exposure (a minimum value, a maximum value, and an intermediate value therebetween) are formed through a single exposure step, and through development of these, the fifth photoresist 55 is formed. The regions under an intermediate amount of exposure are defined by the halftone mask. When the photoresist film is made of a negative type photoresist, the regions under the maximum amount of exposure have the largest film thickness; openings are formed in the regions under the minimum amount of exposure; and dents (portions that are thinner than the regions under the maximum amount of exposure) are formed in the regions under an intermediate amount of exposure. When a positive type photoresist is used, the regions under the minimum amount of exposure have the largest film thickness; openings are formed in the regions under the maximum amount of exposure; and dents are formed in the regions under an intermediate amount of exposure.

The fifth mask is designed so as to define a pattern of drain electrodes and source electrodes of the TFTs and lines (local lines) such as inter-transistor connection lines in the local line regions L, and define a pattern of lines having the first layer structure, e.g., global lines, in the global line regions G. Furthermore, the regions under an intermediate amount of exposure are designed so as to define regions x, in the local line regions L, which lack any pattern of drain electrodes and source electrodes of the TFTs and lines (local lines) such as inter-transistor connection lines.

Therefore, the fifth photoresist 55 obtained through development has dents in the regions x in the local line regions L. In other words, it is thinner than the regions defining a pattern of electrodes and lines. Moreover, it also has openings in regions y, in the global line regions G, which lack any pattern of lines.

Then, as shown in FIG. 9(c), the portions of the second electrically conductive film 30B′ that are not covered by the fifth photoresist 55, i.e., the portions located in the regions y, are removed by a dry etching technique or a wet etching technique. Irrespective of whichever etching method is used, the materials and the etching method for these films 30A′ and 30B′ are to be selected so that the etching rate of the first electrically conductive film 30A′ is lower than the etching rate of the second electrically conductive film 30B′. Therefore, only the second electrically conductive film 30B′ not being covered by the fifth photoresist 55 is patterned, whereas the first electrically conductive film 30A′ is hardly etched. As a result, in the global line regions G, the second electrically conductive film 30B′ is patterned so that an upper layer 30B to be used as the global lines is obtained.

On the other hand, the local line regions L are covered by the fifth photoresist 55. In this example, the pattern of source and drain electrodes of the TFTs and local lines such as inter-transistor connection lines are covered by the thick portions of the fifth photoresist 55, whereas the regions (x) other than the aforementioned pattern are covered by the thin portions of the fifth photoresist 55. Therefore, the portions of the first electrically conductive film 30A′ that are located in the local line regions L can not only escape patterning through this etching step, but also avoid the etching atmosphere.

Then, as shown in FIG. 9(d), the fifth photoresist 55 is left as it is, but subjected to an ashing treatment, thereby reducing the thickness of the fifth photoresist 55. As a result, the thin portions of the fifth photoresist 55 located in the regions x are removed, thereby exposing the first electrically conductive film 30A′. The fifth photoresist 55 after the ashing treatment has openings in the regions x and the regions y.

Then, as shown in FIG. 9(e), the fifth photoresist after the ashing treatment is used to etch away the portions of the first electrically conductive film 30A′ that are not covered by the fifth photoresist 55 (i.e., portions which are exposed through the openings). As the etching method, a dry etching technique or a wet etching technique is used, for example. This removes the portions of the first electrically conductive film 30A′ that are located in the regions x and the regions y, thereby leaving the lower layer 30A. Thus, a source metal layer 30 including the lower layer 30A and upper layer 30B is obtained.

In this example, similarly to the production method described above, source electrodes 9s and drain electrode 9d composed of the lower layer 30A are obtained in the local line regions L, whereby TFTs 10 are fabricated. Furthermore, local lines composed of the lower layer 30A are formed, e.g., inter-transistor connection lines 9a. On the other hand, in the global line regions G, global lines 9g having a multilayer structure (first layer structure) of the lower layer 30A and the upper layer 30B are formed. Thereafter, the fifth photoresist 55 is removed as shown in FIG. 9(f).

Then, as shown in FIG. 9(g), a dielectric protection layer (passivation layer) 12 which covers the TFTs 10 and the source metal layer 30 is provided. The material, thickness, and method of formation of the dielectric protection layer 12 are identical to the material, thickness, and method of formation described earlier with reference to FIG. 4(l). Thereafter, although not shown, a planarization film may be formed on the dielectric protection layer 12. In this manner, the semiconductor device 100A is produced.

With the above-described production method, effects similar to those of the method described above with reference to FIG. 3 to FIG. 5 or FIG. 6 to FIG. 8 are obtained. Furthermore, with the above production method, an etching to form the upper layer 30B can be performed while covering the portions to become channels of the semiconductor layer 7 with both the first electrically conductive film 30A′ and the fifth photoresist 55. This makes it unlikely for the first electrically conductive film 30A′ to be damaged by the etching atmosphere, thereby better protecting the portions to become the channel regions in the semiconductor layer 7.

### Second Embodiment

FIG. 10 is a cross-sectional view illustrating an exemplary semiconductor device 100B according to a second embodiment of the present invention. The semiconductor device 100B differs from the semiconductor device 100A shown in FIG. 1 in that it includes an etch stop layer covering channel regions of the semiconductor layer. In FIG. 10, component elements similar to those in FIG. 1 are denoted by identical reference numerals.

The semiconductor device 100B includes an etch stop layer 8 between: a semiconductor layer 7; and source electrodes 9s and drain electrodes 9d. The etch stop layer 8 is provided so as to at least cover channel regions 7c of the semiconductor layer 7. The etch stop layer 8 may be a silicon oxide film, a silicon nitride film, a silicon oxynitride film, or a multilayer film thereof. The etch stop layer 8 has a thickness of e.g. not less than 50 nm and not more than 400 nm. Each source electrode 9s and each drain electrode 9d are disposed so as to be in contact with a portion of the surface of the semiconductor layer 7 that is not covered by the etch stop layer 8. Note that each source electrode 9s and each drain electrode 9d may be in contact with the semiconductor layer 7 within an opening that is formed in the etch stop layer 8. Moreover, the etch stop layer 8 may extend across substantially the entire substrate 1, similarly to the gate dielectric layer 5. The other construction is similar to that of the semiconductor device 100A, and descriptions thereof are omitted.

According to the present embodiment, effects similar to those of the first embodiment are obtained. Specifically, deteriorations in the TFT characteristics due to a decrease in the covering ability of the dielectric protection layer 12 can be suppressed. Moreover, circuit characteristics can be improved by keeping the resistance of the global lines 9g low. In the present embodiment, the portions of the semiconductor layer 7 to become channel regions are protected by the etch stop layer 8 during the etching step for forming the source electrodes 9s and drain electrodes 9d. Therefore, as compared to the first embodiment, the damage which is done to the semiconductor layer 7 during etching can be better reduced.

The semiconductor device 100B can be produced by a similar method to that of the semiconductor device 100A except that, after patterning the semiconductor layer 7, the etch stop layer 8 is formed before forming the electrically conductive film 30′ for sources. The etch stop layer 8 can be forming a silicon oxide film (SiO₂ film) so as to cover the semiconductor layer 7 by a CVD technique, and patterning it, for example.

### Third Embodiment

Hereinafter, a third embodiment of the semiconductor device according to the present invention will be described. In the present embodiment, the TFTs 10 shown in FIG. 1 are used as pixel TFTs of an active matrix substrate (TFT substrate) for a liquid crystal display device.

FIG. 11 is a plan view illustrating a portion of an exemplary TFT substrate 100C, showing a portion of the display region of the TFT substrate 100C. The TFT substrate 100C has a display region which includes a plurality of pixels 101. In the display region, a plurality of source bus lines 31, a plurality of gate bus lines 21, a plurality of TFTs (pixel TFT) 10 formed at the respective intersections thereof, and pixel electrodes 41 formed for the respective pixels 101 are provided, these being formed on an electrically insulative substrate. A storage capacitor (not shown) may be provided in each pixel 101.

The TFTs 10 have the construction shown in FIG. 1(a), for example. Of each TFT 10, a source electrode 9s is electrically connected to a source bus line 31, a gate electrode 3 to a gate bus line 21, and a drain electrode 9d to a pixel electrode 41.

The pixel electrodes 41 are made of a transparent electrically conductive film (e.g. ITO (Indium Tin Oxide) or IZO (registered trademark)(Indium Zinc Oxide) film), for example. The pixel electrodes 41 have a thickness of e.g. not less than 20 nm and not more than 200 nm.

In this example, the source bus lines 31 extend in an orthogonal direction to the gate bus lines 21. The source bus lines 31 and the source electrodes 9s are connected by lines 9b each extending from the side face of a source bus line 31 in a direction different from that of the source bus line 31. The source bus lines 31 are global lines 9g, having the first layer structure. The lines 9b, the source electrodes 9s, and the drain electrodes 9d have the second layer structure. The structures of the lines 9b, source electrodes 9s, and drain electrodes 9d are not limited to the above, so long as at least the portions of the source electrodes 9s and the drain electrodes 9d that are located on the semiconductor layer 7 have the second layer structure, as was mentioned earlier.

In FIG. 11, the TFTs 10 shown in FIG. 1 are used as the pixel TFTs; instead, etch-stop type TFTs as shown in FIG. 10 may be used. In the case where peripheral circuits are integrally formed in the non-display region of the substrate 1, the circuitry TFT to be used in the peripheral circuits may have the same structure as that of the aforementioned pixel TFTs. Furthermore, some lines of the peripheral circuits may have the same wiring structure (first layer structure) as that of the source bus lines 31.

Although an active matrix substrate of a liquid crystal display device is described herein as an example, the present invention is also applicable to active matrix substrates of other display devices, such as organic EL display devices.

### Fourth Embodiment

Hereinafter, a fourth embodiment of the semiconductor device according to the present invention will be described. In the present embodiment, the TFTs 10 shown in FIG. 1 are used as circuitry TFTs of an active matrix substrate (TFT substrate) for a liquid crystal display device.

FIG. 12(a) is a schematic plan view showing a TFT substrate 100D according to the present embodiment. The TFT substrate 100D has a display region 130 which includes a plurality of pixels 101, and a region (non-display region) 140 other than the display region. In the non-display region 140, a gate driver 110 and a source driver 120 are provided. The gate driver 110 is formed integrally with the TFT substrate 100D. The source driver 120 does not need to be formed integrally; instead, a separately-produced source driver IC or the like may be mounted on the TFT substrate 100D by a known method.

The construction of pixels 101 of the TFT substrate 100D is shown in FIG. 12(b). As shown in FIG. 12(b), each pixel 101 includes a pixel TFT, a source bus line 31, a gate bus line 21, and a pixel electrode 41. The drain electrode of the pixel TFT is connected to the pixel electrode 41, and the source electrode is connected to the source bus line 31. The gate electrode of the pixel TFT is connected to the gate bus line 21.

The gate bus line 21 is connected to the output of the gate driver 110, and subjected to linear-sequential scanning. The source bus line 31 is connected to the output of the source driver 120, and receives a display signal voltage (gray scale voltage).

Next, FIG. 13(a) is a block diagram describing the construction of a shift register 110A included in the gate driver 110. The shift register 110A is supported on an electrically insulative substrate that composes the TFT substrate 100D, e.g., a glass substrate. At least one of the TFTs (circuitry TFTs) constituting the shift register 110A is the TFT 10 shown in FIG. 1.

Among a plurality of stages (1st to N^{th} stages) of the shift register 110A, FIG. 13(a) schematically shows only the six stages from the first STAGE(1) to the sixth STAGE(6). The stages have substantially the same structure, and are cascaded. The outputs from the respective stages of the shift register 110A are supplied to the respective gate bus lines 21 in the display region 130. Such a shift register 110A is described in International Publication No. 2011/024499 by the Applicants, for example. The entire disclosure of International Publication No. 2011/024499 is incorporated herein by reference.

Each stage of the shift register 110A includes an input terminal for receiving a set signal S, an input terminal for receiving a reset signal R, an output terminal for outputting an output signal Q, and input terminals for receiving four clock signals CKA, CKB, CKC, and CKD of respectively different phases. To STAGE(1), a gate start pulse GSP-O is input as the set signal S. The output terminal of each stage is connected to a corresponding gate bus line 21. Moreover, the output terminals of STAGE(2) to STAGE(N−1) are each connected to the input terminal for receiving a set signal in the respective next stage.

In FIG. 13(a), lines VSS, CK1, CK1B, CK2, CK2B, and CLR represent trunk lines. The lines CK1, CK1B, CK2, and CK2B are trunk lines for gate clock signals; the line VSS is a trunk line for low-potential DC voltage VSS; and the line CLR is a trunk line for the clear signal CLR. These trunk lines are provided in a region on the opposite side of the shift register 110A from the display region 130, for example.

FIG. 13(b) is a diagram showing the construction of circuitry that is employed in one stage (an N^{th} stage) of the shift register 110A. As shown in FIG. 13(b), this circuit includes thin film transistors MA, MB, MI, MF, MJ, MK, ME, ML, MN, and MD and a capacitor CAP1. Preferably, the conductivity types of these thin film transistors (TFTs) are all p-type, or all n-type. These TFTs are oxide semiconductor TFTs, for example. Alternatively, they may be amorphous silicon TFTs or microcrystalline silicon TFTs. At least one or all of these TFTs have the construction which has been described above with reference to FIG. 1.

FIG. 14 is a schematic illustration for describing the layout of the shift register 110A, corresponding to the construction shown in FIG. 13(a). To discuss the circuit of an N^{th} stage (where N is a positive integer) in FIG. 14, among the four clock signals supplied to this circuit, the first clock CKA and the second clock CKB are supplied from the trunk lines for clock signals; the third clock CKC to be supplied to the thin film transistor MF is supplied from the N+1^{th} circuit; and the fourth clock CKD to be supplied to the thin film transistor MK is supplied from the N−1^{th} circuit.

In the present embodiment, the source metal layer includes trunk lines 9g providing interconnection between the circuits of respective stages, lines (global-local connection lines) 9c connecting a trunk line 9g to a specific TFT in each circuit (which herein is the thin film transistor MI), source and drain electrodes of the TFTs in each circuit, and lines (inter-transistor connection lines) 9a providing interconnection between TFTs (which herein are thin film transistors MI and MK) of respective circuits. The trunk lines 9g are global lines having the first layer structure. On the other hand, the source and drain electrodes of each TFT have the second layer structure. Furthermore, in this example, both of the global-local connection lines 9c and the inter-transistor connection lines 9a are local lines having the second layer structure.

In the present embodiment, for example, the region in which the plurality of trunk lines 9g are disposed may define a global line region G, whereas the regions in which the circuits of respective stages are formed may define local line regions L. As was described earlier, the global line region G and the local line regions L may partially overlap.

According to the present embodiment, similarly to the earlier-described embodiments, the structure of the trunk lines (global lines) 9g and the connection lines (local lines) 9a and 9b can each be optimized. Therefore, while ensuring a rapid circuit operation by keeping the resistance of the trunk lines 9g low, fluctuations in the TFT characteristics due to a decrease in the covering ability of the passivation film can be suppressed.

In the example shown in FIG. 14, the global-local connection lines 9c and the inter-transistor connection lines 9a have the second layer structure; however, some or all of these connection lines 9c and 9a may have the first layer structure. The structures of the connection lines 9c and 9a may be appropriately optimized in accordance with the layout and circuit constants. For example, the first layer structure may be adopted in the case where low line resistance is required, whereas the second layer structure may be adopted in the case where a high density layout is required.

The above-described TFT substrates 100A to 100D are used in a liquid crystal display device, for example. With reference to FIG. 15, the structure of a liquid crystal display device 1000 in which the TFT substrate 100A to 100D is used will be described.

The liquid crystal display device 1000 includes a TFT substrate 100, a substrate (e.g., a glass substrate) 200, and a liquid crystal layer 80. A counter electrode 82 is formed on the liquid crystal layer 80 side of the substrate 200. As the TFT substrate 100, the TFT substrate 100C or 100D can be used, for example. Alternatively, pixel electrodes 41 may be formed on the aforementioned TFT substrate 100A or 100B, and this may be used as the TFT substrate 100. In the liquid crystal display device 1000, voltage is applied across the liquid crystal layer 80 existing between the pixel electrodes 41 and the counter electrode 82. On the liquid crystal layer 80 side of the pixel electrodes 41 and the counter electrode 82, an alignment film (e.g., a vertical alignment film) is formed as necessary. The liquid crystal display device 1000 is a vertical alignment mode (VA mode) liquid crystal display device, for example. It will be appreciated that the liquid crystal display device according to an embodiment of the present invention is not limited thereto, but is also applicable to lateral field mode liquid crystal display devices having pixel electrodes and a counter electrode on the TFT substrate, e.g., the In-Plane Switching(IPS) mode or the Fringe Field Switching(FFS) mode, for example. The TFT structure for IPS mode and FFS mode liquid crystal display devices is well known, and the descriptions thereof are omitted.

Moreover, the display device according to an embodiment of the present invention may include a TFT substrate, and a display medium layer such as a liquid crystal layer, and may be an organic electroluminescence (EL) display device and an inorganic electroluminescence display device or the like, for example.

### INDUSTRIAL APPLICABILITY

Embodiments of the present invention are broadly applicable to various semiconductor devices having TFTs. In particular, they are advantageously applied to various semiconductor devices having oxide semiconductor TFTs, because of being able to suppress deterioration of the oxide semiconductor layer. Embodiments of the present invention are also applicable to: circuit boards such as active matrix substrates; display devices such as liquid crystal display devices, organic electroluminescence (EL) display devices, and inorganic electroluminescence display devices; imaging devices such as image sensor devices; electronic devices such as image input devices and fingerprint reader devices; and so on.

### REFERENCE SIGNS LIST

10 TFT

1 substrate

3 gate electrode

5 gate dielectric layer

7 semiconductor layer

7c channel region

9s source region

9d drain region

9g global lines

9a inter-transistor connection line

9b global line-transistor connection line

12 dielectric protection layer

20 gate metal layer

21 gate bus line

30 source metal layer

31 source bus line

41 pixel electrode

51, 52, 53, 54, 55 photoresist

100A, 100B, 100C, 100D TFT substrate (semiconductor device)

1. A semiconductor device comprising:
a substrate;
a plurality of thin film transistors supported on the substrate, each of the plurality of thin film transistors including a gate electrode, a gate dielectric layer formed on the gate electrode, a semiconductor layer formed on the gate dielectric layer, and a source electrode and a drain electrode being provided on the semiconductor layer and electrically connected to the semiconductor layer;
a source metal layer including the source electrodes and the drain electrodes and a global line which supplies a common signal to the plurality of thin film transistors, the global line being made of a same electrically conductive film as the source electrodes and the drain electrodes; and
a dielectric protection layer covering the plurality of thin film transistors and the source metal layer, wherein,
the metal layer includes a lower layer and an upper layer stacked on a portion of the lower layer;
the global line has a first layer structure including the lower layer and the upper layer; and
at least a portion of each source electrode and of each drain electrode that is located on the semiconductor layer has a second layer structure including the lower layer but not including the upper layer.

2. The semiconductor device of claim 1, wherein,
the surface of the upper layer in the first layer structure is in contact with the dielectric protection layer; and
the surface of the lower layer in the second layer structure is in contact with the dielectric protection layer.

3. The semiconductor device of claim 1, wherein the lower layer includes a first layer, and the upper layer includes a second layer formed on the first layer by using a different material from that of the first layer.

4. The semiconductor device of claim 1, wherein the source metal layer further includes global line-transistor connection lines which electrically connect the global line respectively to the plurality of thin film transistors, the global line-transistor connection lines having the second layer structure.

5. The semiconductor device of claim 1, wherein the source metal layer further includes an inter-transistor connection line which electrically connects at least two of the plurality of thin film transistors, the inter-transistor connection line having the second layer structure.

6. The semiconductor device of claim 1, wherein the lower layer is thinner than the upper layer.

7. The semiconductor device of claim 1, wherein, when viewed from a normal direction of the substrate, at least a portion of each source electrode and of each drain electrode that overlaps the gate electrode has the second layer structure.

8. The semiconductor device of claim 1, wherein, when viewed from a normal direction of the substrate, there is a distance of 10 μm or more between the global line and the semiconductor layer.

9. The semiconductor device of claim 1, wherein the surface of channel regions of the plurality of thin film transistors is in contact with the dielectric protection layer.

10. The semiconductor device of claim 1, wherein an etch stop layer is provided between the semiconductor layer and the source electrodes and drain electrodes of the plurality of thin film transistors.

11. The semiconductor device of claim 1, comprising a shift register, wherein
the shift register includes at least a part of the plurality of thin film transistors.

12. The semiconductor device of claim 1, having a display region including a plurality of pixels, wherein
each of the plurality of pixels includes at least one thin film transistor among the plurality of thin film transistors.

13. The semiconductor device of claim 1, wherein the semiconductor layer is an oxide semiconductor layer.

14. The semiconductor device of claim 13, wherein the oxide semiconductor layer is an In—Ga—Zn—O type oxide layer.

15. A production method for a semiconductor device including a plurality of thin film transistors and a global line which supplies a common signal to the plurality of thin film transistors, comprising:
step (a) of forming a gate metal layer including a plurality of gate electrodes on a substrate;
step (b) of forming a gate dielectric layer on the gate metal layer;
step (c) of forming a semiconductor layer in plural parts on the gate dielectric layer to become active layers of the plurality of thin film transistors;
step (d) of forming a first electrically conductive film on the semiconductor layer and the gate dielectric layer, and then forming a second electrically conductive film on the first electrically conductive film;
step (e) of patterning the first electrically conductive film and the second electrically conductive film to form a source metal layer including source electrodes and drain electrodes of the plurality of thin film transistors and the global line, the source metal layer including a lower layer made of the first electrically conductive film and an upper layer made of the second electrically conductive film, the upper layer being stacked on a portion of the lower layer; and
step (f) of forming a dielectric protection layer on the source metal layer, wherein,
the global line has a first layer structure including the lower layer and the upper layer; and
at least a portion of each source electrode and of each drain electrode that is located on the semiconductor layer has a second layer structure including the lower layer but not including the upper layer.

16. The production method for a semiconductor device of claim 15, wherein
step (e) comprises
step (e1) of patterning the second electrically conductive film to form the upper layer, and
step (e2), performed after step (e1), of patterning the first electrically conductive film to form the lower layer.

17. The production method for a semiconductor device of claim 15, wherein,
the semiconductor device includes a global line region and a local line region; and
step (e) comprises
step (e1′) of patterning the second electrically conductive film by using a mask covering the global line region to remove a portion of the second electrically conductive film that is located in the local line region, and
step (e2′), performed after step (e1′), of patterning the first electrically conductive film and the second electrically conductive film to form the lower layer from the first electrically conductive film and the upper layer from the second electrically conductive film.

18. The production method for a semiconductor device of claim 17, wherein step (e2′) comprises a step of patterning the first electrically conductive film and the second electrically conductive film through a photolithography process using a gradation mask.

19. The production method for a semiconductor device of claim 15, wherein the semiconductor layer is an oxide semiconductor layer.

20. The production method for a semiconductor device of claim 19, wherein the oxide semiconductor layer comprises an In—Ga—Zn—O type oxide.

21. (canceled)
